(19) United States
(12) Patent Application Publication
(10) Pub. No.: US 2026/0214954 A1
(43) Pub. Date: Jul. 23, 2026

(54) Method for forming amorphous surface to terminate defect exposure

(71) Applicant: LEAP Semiconductor Corp., Taoyuan City (TW)

(72) Inventors: Wen-Chung LI, Taoyuan City (TW); Kai-Chi Hsiao, Taoyuan City (TW)

(21) Appl. No.: 19/173,126

(22) Filed: Apr. 8, 2025

(30) Foreign Application Priority Data
Jan. 17, 2025 (TW) 114102162

(51) Int. Cl. H01L 21/04; H01L 21/263

(52) U.S. Cl. CPC H10D 62/8325; H10P 34/40

(57) ABSTRACT

The present invention discloses a method for forming an amorphous surface to terminate defect exposure, that is, a method for forming an amorphous surface on the surface of silicon carbide wafer. Firstly, the present invention provides a silicon carbide wafer, then cleans the silicon carbide wafer. Finally, the present invention forms a surface amorphous layer on a silicon carbide wafer through the physical top-down technology to terminate exposed defects.

### BACKGROUND OF THE INVENTION

### 1. Field of the Invention

The present invention relates to a method for forming an amorphous surface, and more particularly to a method for forming an amorphous surface on silicon carbide to terminate defect exposure.

### 2. Description of the Prior Art

Currently, commercially mass-produced silicon carbide (SiC) wafer predominantly features a 4° off-axis orientation as a substrate. The wafer surface is 4° tilted from the c-axis ([0001] direction) toward [1120], forming a terrace-step structure. Although this off-axis design effectively reduces the formation of polytypes and enhances epitaxial growth quality, however, this off-axis design also brings technical challenges in controlling the generation of dislocations. Dislocations may extend into the epitaxial layer during the subsequent epitaxial process, and, in some cases, interact with basal plane dislocations (BPD), other defects and stress. That induces macroscopic defects such as carrot defects, comet defects, and triangle defects and cause irreversible damage to the performance of subsequently stacked devices. Despite advancements in defect reduction, various defects including threading dislocation, basal plane dislocations, and stacking faults remain difficult to eliminate.

As mentioned above, threading dislocation is one of the primary defects in 4° off-axis silicon carbide (SiC) wafer. During epitaxial growth, whether for homogeneous silicon carbide (SiC) epitaxy or heterogeneous gallium nitride epitaxy, threading dislocations propagate and extend from the substrate into the epitaxial layer. Even in high-quality silicon carbide (SiC) wafers, the total defect density, comprising all types of dislocations, remains between hundreds to thousands of dislocations per unit area (cm⁻²).

At present, no effective strategy exists to control dislocation density during crystal growth or to prevent dislocations in the substrate from propagating and extending into the epitaxial layer. Therefore, defects from the substrate continue to propagate and to extend into the epitaxial layer, deteriorating device performance by reducing breakdown voltage, increasing leakage current, and compromising reliability. Suppressing defect propagation improves subsequent epitaxial layer quality and effectively enhancing device yield and reliability.

### SUMMARY OF THE INVENTION

The present invention discloses a method for forming an amorphous surface to terminate defect exposure, especially a method for forming an amorphous layer on the surface of a silicon carbide (SiC) wafer.

The present invention discloses a method for forming an amorphous layer on the surface of a silicon carbide (SiC) wafer. The method comprises the following: (a) providing a commercially available silicon carbide (SiC) wafer, (b) cleaning the wafer by using a standard cleaning process (RCA Clean) to achieve the surface cleanliness standard, and (c) exposing the silicon carbide (SiC) wafer to a plasma source to form an amorphous layer on the surface.

The present invention discloses a method for forming an amorphous layer on the surface of a silicon carbide (SiC) wafer. The method comprises: (a) providing a commercially available silicon carbide (SiC) wafer, (b) cleaning the wafer by using a standard cleaning process (RCA Clean) to achieve the surface cleanliness standard, and (c) subjecting the silicon carbide (SiC) wafer to an ion milling beam to process the surface to form an amorphous layer on the surface.

The present invention provides a method for forming an amorphous layer on the surface of a silicon carbide (SiC) wafer. One of the advantages is that the invention can be performed at room temperature or low temperature, well below the brittle-to-ductile transition temperature (BDTT) of silicon carbide (SiC) wafer, preventing defect propagation.

The present invention provides a method for forming an amorphous layer on the surface of a silicon carbide (SiC) wafer. One of the advantages is that a localization energy can be applied to the silicon carbide (SiC) wafer surface to break the bonds on the surface, and to form an amorphous layer on the surface.

The present invention provides a method for forming an amorphous layer on the surface of a silicon carbide (SiC) wafer. One of the advantages is that the invention can suppress defect propagation, extension, and reduce defect density in the subsequent epitaxial layer.

The present invention provides a method for forming an amorphous layer on the surface of a silicon carbide (SiC) wafer. One of the advantages is that the invention uses a commercially available 4° off-axis silicon carbide (SiC) wafer, which significantly reduces the defect density in the subsequent epitaxial layer without changing the crystal growth conditions.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A is a flowchart showing a method for forming an amorphous layer on the surface of the silicon carbide (SiC) wafer according to a schematic diagram of the present invention.

FIG. 1B is a flowchart showing a plasma treatment method for forming an amorphous layer on the surface of the silicon carbide (SiC) wafer according to a schematic diagram of the present invention.

FIG. 2A is a flowchart showing a method for forming an amorphous layer on the surface of the silicon carbide (SiC) wafer according to a schematic diagram of the present invention.

FIG. 2B is a flowchart showing an ion milling method for forming an amorphous layer on the surface of the silicon carbide (SiC) wafer according to a schematic diagram of the present invention.

### DESCRIPTION OF THE PREFERRED EMBODIMENT

The present invention discloses a method for forming an amorphous layer on the surface of silicon carbide (SiC) wafer for terminating defect exposure.

The present invention provides a method for forming an amorphous layer on the surface of a silicon carbide (SiC) wafer, wherein two different technical methods can include the following: one is a plasma treatment method, and the other is an ion milling method, both are used to induce an amorphous layer on the surface. The plasma treatment method, and the ion milling method involve treating the single crystal silicon carbide (SiC) wafer by using a physical “top-down” technology, to form an amorphous layer on the surface of the silicon carbide (SiC) wafer.

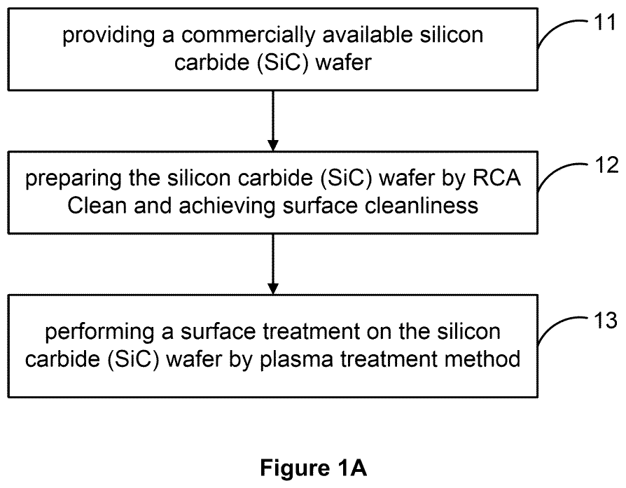

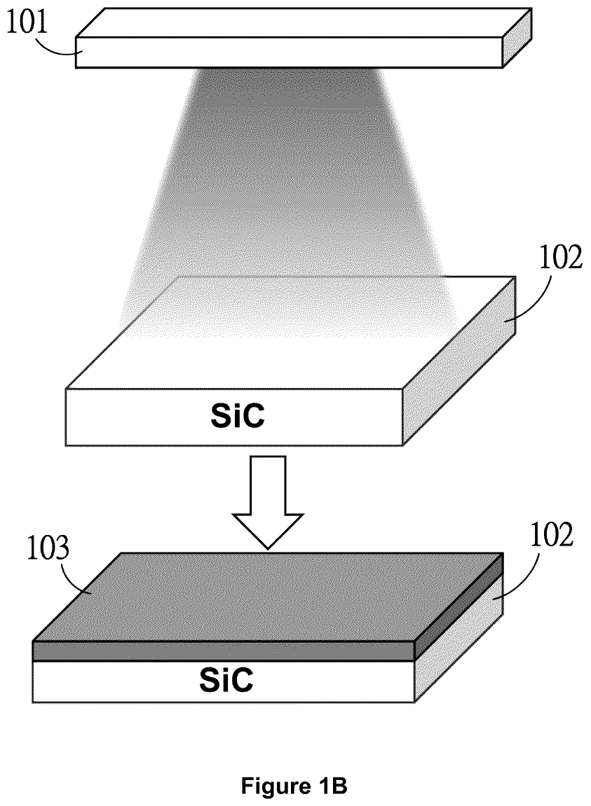

FIG. 1A shows a method for forming an amorphous layer on the surface of a silicon carbide (SiC) wafer according to the present invention. As shown in step 11 of FIG. 1A, a commercially available silicon carbide (SiC) wafer is provided, including alternatively 6-inch and 8-inch wafer.

The present invention provides a method for forming an amorphous layer on the surface of a silicon carbide (SiC) wafer, as further shown in step 12 of FIG. 1A, where the wafer is prepared by an “RCA Clean” process. It is worth noting that the “RCA Clean” process is a widely used and standardized wafer cleaning method that effectively cleans surface contaminants and achieves the required surface cleanliness for silicon carbide (SiC) wafer.

Continuing as further shown in step 13 of FIG. 1A, the present invention uses a plasma treatment method of a physical “top-down” technology, wherein the silicon carbide (SiC) wafer is exposed to a plasma source to form an amorphous layer on the surface. The silicon carbide (SiC) wafer is treated by using a plasma source 101. Also, a plasma source 101 used in the plasma treatment method is selected from the group consisting of argon (Ar), helium (He), neon (Ne), hydrogen (H₂), and nitrogen (N₂). The plasma density ranges from 10⁹ cm⁻³ to 10¹⁵ cm⁻³, and the operating temperature for the plasma treatment method is below 300° C. That is, the surface treatment is performed on the silicon carbide (SiC) wafer by using a plasma treatment method to form an amorphous layer on the surface of the silicon carbide (SiC) wafer.

Next, as shown in FIG. 1B, the present invention provides a method for forming an amorphous layer on the surface of a silicon carbide (SiC) wafer through a plasma treatment method. A high-energy plasma source 101 used as a physical “top-down” technology. The plasma induces localized disruption of crystalline structure on the silicon carbide (SiC) wafer surface and, thereby forming an amorphous layer 103. During the plasma treatment method, the silicon carbide (SiC) wafer 102 is placed in a chamber. The wafer is then treated with plasma, causing lattice disruption at the surface. This results in the formation of amorphous layer 103. The amorphous layer on the surface of the silicon carbide (SiC) wafer 102 has a thickness below 1 micrometer. The optimal thickness ranges from 1 nanometer to 10 nanometers, corresponding to 3 atomic layers to 30 atomic layers. The silicon carbide (SiC) wafer with the amorphous layer 103 structure can be used as a substrate for the subsequent epitaxial process. This process can significantly reduce the defect density in the subsequent epitaxial layer.

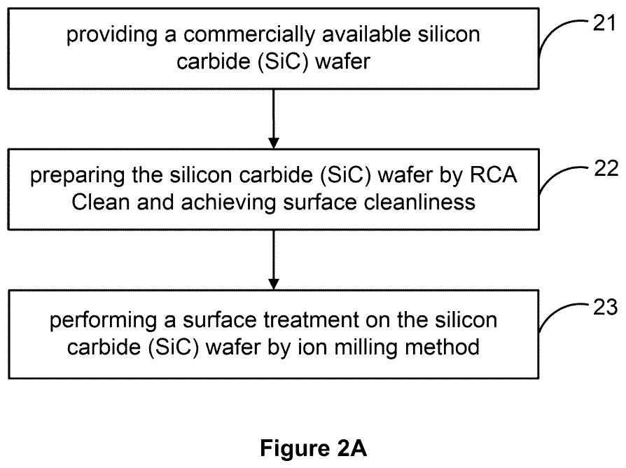

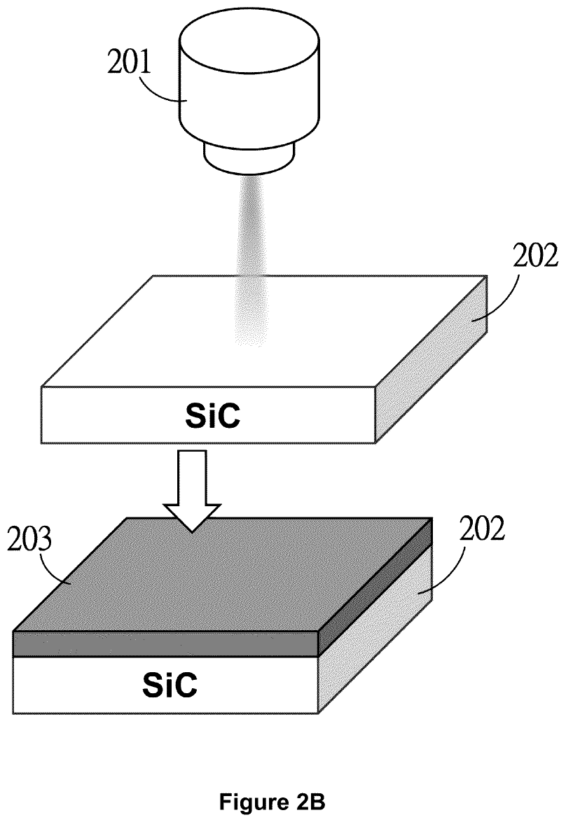

FIG. 2A shows a method for forming an amorphous layer on the surface of a silicon carbide (SiC) wafer according to the present invention. As shown in step 21 of FIG. 2A, a commercially available silicon carbide (SiC) wafer is provided. The wafer includes alternatively 6-inch and 8-inch in size.

The present invention provides a method for forming an amorphous layer on the surface of a silicon carbide (SiC) wafer. As further shown in step 22 of FIG. 2A, the wafer is prepared by an “RCA Clean” process. It is worth noting that the “RCA Clean” process is a widely used and standardized wafer cleaning method that effectively cleans surface contaminants and achieves the required surface cleanliness for silicon carbide (SiC) wafer.

The present invention provides a method for forming an amorphous layer on the surface of a silicon carbide (SiC) wafer. As further shown in step 23 of FIG. 2A, the method uses an ion milling method of a physical “top-down” technology. The ion milling method is applied to process the surface of the silicon carbide (SiC) wafer. This process induces a localized disruption of crystalline structure on the surface of the silicon carbide (SiC) wafer and forms an amorphous layer. That is, the surface treatment is performed on the silicon carbide (SiC) wafer by using an ion milling method to form an amorphous layer on the surface of the silicon carbide (SiC) wafer.

As shown in FIG. 2B, the present invention provides an ion milling method for forming an amorphous layer on the surface of a silicon carbide (SiC) wafer. As shown in FIG. 2B, the source for ion milling is composed of which used in ion beam 201 such as xenon ions (Xe⁺), neon ions (Ne⁺), argon ions (Ar⁺), and gallium ions (Ga⁺). Then, the ion beams induce localized disruption of the crystalline structure at the surface of the silicon carbide (SiC) wafer. The energy of the ion beam ranges from 100 electron volts (eV) to 100 kiloelectron volts (keV). The ion fluences of an ion beam is between 10¹⁰ cm⁻² and 10¹⁸ cm⁻² , corresponding to a current density between 1 μA·cm⁻² to hundreds of mA·cm⁻². The operating temperature of the ion milling method is below 300° C. The amorphous layer has a thickness of less than 1 micrometer. The optimal thickness ranges from 1 nanometer to 10 nanometers, corresponding to 3 atomic layers to 30 atomic layers. The silicon carbide (SiC) wafer with the amorphous layer 203 can be used as a substrate for the subsequent epitaxial process. This method significantly reduces defect density in the epitaxial layer.

The present invention guides “threading dislocations” in the wafer toward the ending surface, where their propagation is effectively hindered. This process suppresses and terminates their continuity. By using this method, the amorphous layer created on the single crystal surface serves as a defect termination region. It effectively pins dislocations at the interface between the single crystal and the amorphous layer and prevents their extension into the subsequent epitaxial layer. Additionally, the optimized thickness of the amorphous layer ensures that the subsequent epitaxial layer inherits and maintains the same polytype of the substrate. Also, the optimized thickness of the amorphous layer provides stress relaxation via recrystallization while not forming polytypes in the subsequent epitaxy.

The amorphous layer of the present invention is formed by using a physical “top-down” technology. The methods involve the use of a high density plasma or a high energy ion beam to physically induce localized disruption on the surface crystalline region and to form an amorphous layer on the wafer surface.

When the amorphous layer of the present invention is formed, it serves as a defect termination layer. The subsequently deposited layer can rearrange atoms to occupy the correct position. Additionally, an ultra-thin amorphous layer can still transmit the lattice force field or electrostatic potential from the substrate. This helps regulate the deposition of species, ensuring that they follow the stacking sequence of the substrate. As a result, the occurrence of polytypes in the epitaxial layer is reduced.

The thickness of the amorphous layer in the present invention is controlled within 1 micrometer, preferably within 10 nanometers. That is beneficial for the subsequent epitaxial process to grow according to the polytype of the substrate, avoiding the occurrence of the other polytypes during epitaxy. The stress relaxation may also occur via the recrystallization of the amorphous layer without the formation of the polytypes.

The amorphous layer of the present invention is formed at a low temperature (T<300° C.) and localized energy disrupts the surface crystalline and surface bonds of the silicon carbide (SiC) wafer, producing an amorphous layer on the surface.

The formation of the amorphous layer in the present invention interrupts defect propagation. The optimized thickness is conducive to the transmission of the lattice force field or electrostatic potential from a substrate wafer. This also helps the second homogeneous epitaxial layer maintain the polytype of the substrate. Additionally, the defects in the substrate wafer stop propagating when countering discontinuous lattice structures. In the case of heteroepitaxy, an amorphous layer further prevents defects from propagating and extending into the second heteroepitaxial layer.

The present invention benefits from the amorphous surface of single crystal silicon carbide (SiC) wafer, which enables the termination of defects within the wafer. Such defects including threading dislocations, stacking faults, and basal plane dislocations are terminated at the amorphous surface. As a result, the invention enhances the epitaxial quality and further improves process yield in subsequent device fabrication.

It is understood that various modifications will be apparent to and can be readily made by those skilled-in-the-art without departing from the scope and spirit of this invention. Accordingly, it is not intended that the scope of the claims appended hereto be limited to the description as set forth herein, but rather that the claims be construed as encompassing all the features of patentable novelty that reside in the present invention, including all features that would be treated as equivalents thereof by those skilled-in-the-art to which this invention pertains.

What is claimed is:

1. A method for forming an amorphous layer on a surface of a silicon carbide wafer comprises:
providing a silicon carbide wafer;
preparing said silicon carbide wafer by using a cleaning process; and
performing a surface treatment on said silicon carbide wafer by using a physical top-down technology to form an amorphous layer on said surface of said silicon carbide wafer.

2. The method according to claim 1, wherein said physical top-down technology is selected from a group consisting of a plasma treatment method and an ion milling method.

3. The method according to claim 2, wherein a plasma source used in said plasma treatment method is selected from a group consisting of argon (Ar), helium (He), neon (Ne), hydrogen (H₂), and nitrogen (N₂).

4. The method according to claim 2, wherein said plasma treatment method comprises a plasma having a plasma density ranging from 10⁹ cm⁻³ to 10¹⁵ cm⁻³.

5. The method according to claim 2, wherein an operating temperature of said plasma treatment method comprises below 300° C.

6. The method according to claim 2, wherein an ion beam used in said ion milling method is selected from a group consisting of xenon ions (Xe⁺), neon ions (Ne⁺), argon ions (Ar⁺), and gallium (Ga⁺) ions.

7. The method according to claim 2, wherein said ion milling method comprises an ion beam having an energy between 100 electron volts (eV) and 100 kiloelectron volts (keV).

8. The method according to claim 2, wherein said ion milling method comprises an ion beam having an ion fluences between 10¹⁰ cm⁻² and 10¹⁸ cm⁻² and a current density from 1 μA·cm⁻² to hundreds of mA·cm⁻².

9. The method according to claim 2, wherein an operating temperature of said ion milling method comprises below 300° C.

10. The method according to claim 1, wherein said amorphous layer has a thickness of less than 1 micrometer.

11. A method for forming an amorphous layer on a surface of a silicon carbide wafer, comprising:
providing a silicon carbide wafer;
preparing said silicon carbide wafer by using a cleaning process; and
performing a surface treatment on said silicon carbide wafer by using a physical top-down technology to form an amorphous layer on said surface of said silicon carbide wafer, wherein said physical top-down technology is selected from a group consisting of a plasma treatment method and an ion milling method.

12. The method according to claim 11, wherein a plasma source used in said plasma treatment method is selected from a group consisting of argon (Ar), helium (He), neon (Ne), hydrogen (H₂), and nitrogen (N₂).

13. The method according to claim 11, wherein said plasma treatment method comprises a plasma having a plasma density ranging from 10⁹ cm⁻³ to 10¹⁵ cm⁻³.

14. The method according to claim 11, wherein an operating temperature of said plasma treatment method comprises below 300° C.

15. The method according to claim 11, wherein an ion beam used in said ion milling method is selected from a group consisting of xenon ions (Xe⁺), neon ions (Ne⁺), argon ions (Ar⁺), and gallium (Ga⁺) ions.

16. The method according to claim 11, wherein said ion milling method comprises an ion beam having an energy between 100 electron volts (eV) and 100 kiloelectron volts (keV).

17. The method according to claim 11, wherein said ion milling method comprises an ion beam having an ion fluences between 10¹⁰ cm⁻² and 10¹⁸ cm⁻² and a current density from 1 μA·cm⁻² to hundreds of mA·cm⁻².

18. The method according to claim 11, wherein an operating temperature of said ion milling method comprises below 300° C.

19. The method according to claim 11, wherein said amorphous layer has a thickness of less than 1 micrometer.
